(19) United States
(12) Patent Application Publication
(10) Pub. No.: US 2026/0355894 A1
(43) Pub. Date: Nov. 12, 2026

(54) SUBSTRATE-POLISHING DEVICE INCLUDING PRESSURIZING STRUCTURE FOR APPLYING BIASED LOADS

(71) Applicant: KCTECH CO., LTD., Gyeonggi-do (KR)

(72) Inventor: Ilsung SON, Gyeonggi-do (KR)

(73) Assignee: KCTECH CO., LTD., Gyeonggi-do (KR)

(21) Appl. No.: 19/668,787

(22) Filed: May 5, 2026

(30) Foreign Application Priority Data
May 7, 2025 (KR) 10-2025-0059165

(51) Int. Cl. B24B 37/10; B24B 37/32; H10P 72/00

(52) U.S. Cl. CPC B24B 37/105; B24B 37/32; H10P 72/0428

(57) ABSTRACT

A substrate-polishing device is provided. The substrate-polishing device includes a substrate carrier including a carrier head configured to rotate about a rotation axis, wherein a lower portion of the substrate carrier is configured to grip a substrate and a pressurizing structure connected to the substrate carrier and configured to partially be in contact with an upper portion of the carrier head to apply a biased load to the carrier head, wherein the pressurizing structure includes a plurality of load-generating devices with adjustable height and is configured to apply a biased load to the carrier head through the plurality of load-generating devices.

### CROSS-REFERENCE TO RELATED APPLICATION

This application claims the benefit of Korean Patent Application No. 10-2025-0059165, filed on May 7, 2025, in the Korean Intellectual Property Office (now the Ministry of Intellectual Property (MOIP)), the entire disclosure of which is incorporated herein by reference for all purposes.

### BACKGROUND

### 1. Field of the Invention

One or more embodiments relate to a substrate-polishing device including a pressurizing structure for applying a biased load.

### 2. Description of the Related Art

The manufacture of a semiconductor device requires a chemical mechanical polishing (CMP) operation including polishing, buffing, and cleaning. A semiconductor device has a multilayer structure, and a transistor device having a diffusion region is formed in a substrate layer. In the substrate layer, a connecting metal line is patterned and electrically connected to the transistor device that forms a functional device. It is generally known that a patterned conductive layer is insulated from another conductive layer by an insulating material such as silicon dioxide. As more metal layers and associated insulating layers are formed, a need to planarize insulating materials increases. If planarization is not achieved, manufacturing additional metal layers becomes significantly more difficult due to substantial variations in surface shape. In addition, metal line patterns are formed from insulating materials, and metal CMP processes remove excess metal materials.

A polishing process for polishing a substrate may be performed by rotating a substrate while the substrate is gripped by a substrate carrier and brought into contact with a polishing pad. During the process of polishing the substrate via the substrate carrier, it is necessary to maintain a uniform polishing state across respective regions of the substrate. For example, the polishing rate of an edge region of the substrate may be controlled by adjusting a pressing force applied to the edge region of the substrate.

The above description has been possessed or acquired by the inventor(s) in the course of conceiving the present disclosure and is not necessarily an art publicly known before the present application is filed.

### SUMMARY

Embodiments provide a substrate-polishing device capable of eliminating imbalance in a substrate-polishing profile, particularly imbalance in a polishing profile at an edge region of the substrate.

Embodiments provide a substrate-polishing device capable of applying a biased load to a retainer ring for controlling a polishing profile at the edge of a substrate.

Embodiments provide a substrate-polishing device capable of reducing a rebound phenomenon that may occur during a substrate-polishing process.

The technical aspects obtainable from the embodiments are not limited to the above-mentioned technical aspects, and other unmentioned technical aspects may be clearly understood from the following description by those having ordinary skill in the technical field to which the present disclosure pertains.

According to an aspect, there is provided a substrate-polishing device including a substrate carrier including a carrier head configured to rotate about a rotation axis, wherein a lower portion of the substrate carrier is configured to grip a substrate and a pressurizing structure connected to the substrate carrier and configured to partially be in contact with an upper portion of the carrier head to apply a biased load to the carrier head, wherein the pressurizing structure may include a plurality of load-generating devices with adjustable height and is configured to apply a biased load to the carrier head through the plurality of load-generating devices.

The plurality of load-generating devices may be disposed to form equal angles about the rotation axis of the carrier head.

The pressurizing structure may further include a fixed plate installed on the upper portion of the carrier head, wherein the plurality of load-generating devices is connected to a lower portion of the fixed plate, an upper ring bracket having a ring shape and connected to lower portions of the plurality of load-generating devices, a lower ring bracket having a ring shape and rotatably connected to the upper ring bracket to have a same central axis as the upper ring bracket, and a bearing member configured to connect the upper ring bracket to the lower ring bracket via a bearing.

The upper ring bracket may be connected to the lower ring bracket such that an inner circumferential surface of the upper ring bracket and an outer circumferential surface of the lower ring bracket face each other, and the bearing member may be disposed between the inner circumferential surface of the upper ring bracket and the outer circumferential surface of the lower ring bracket.

The pressurizing structure may include a rubber member having a ring shape, connected to a lower portion of the lower ring bracket, and including a cushioning material, the rubber member may include a first coupling portion formed on a lower side of the rubber member and configured to be in contact with the carrier head, and the carrier head may include a second coupling portion formed on an upper side of the carrier head and configured to engage with the first coupling portion.

Each of the plurality of load-generating devices may include an actuator including a cylinder member and a piston member configured to slide relative to each other in a height direction and one or more joint blocks configured to connect the fixed plate to the upper ring bracket and implement a relative tilting motion of the upper ring bracket with respect to the fixed plate.

The one or more joint blocks may include an upper joint block configured to connect the fixed plate to the cylinder member and implement a relative tilting motion between the fixed plate and the cylinder member.

The one or more joint blocks may include a lower joint block configured to connect the piston member to the upper ring bracket and implement a relative tilting motion between the piston member and the upper ring bracket.

Each of the one or more joint blocks may have a cuboid shape including an upper surface and a lower surface to which different structures are connected, a pair of first side surfaces configured to connect the upper surface to the lower surface in parallel, and a pair of second side surfaces vertically connected to the pair of first side surfaces.

Each of the one or more joint blocks may include an upper portion configured to form the upper surface, a lower portion configured to form the lower surface, a connecting portion configured to connect the upper portion to the lower portion and form the pair of first side surfaces and the pair of second side surfaces, an upper slit formed along at least a portion of a perimeter direction of the pair of first side surfaces and the pair of second side surfaces to space the upper portion apart from the connecting portion, and a lower slit formed along at least a portion of the perimeter direction of the pair of first side surfaces and the pair of second side surfaces to space the lower portion apart from the connecting portion.

Each of the one or more joint blocks further may include a hollow passing through between the upper surface and the lower surface, and a height direction of the hollow may be parallel to a height direction of each of the plurality of load-generating devices.

Each of the one or more joint blocks further may include a first extension formed on each of the first side surfaces to connect the upper portion to the connecting portion and a second extension formed on each of the second side surfaces to connect the lower portion to the connecting portion.

The first extension may be disposed at a widthwise center of each of the first side surfaces, and the second extension may be disposed at a widthwise center of each of the second side surfaces.

Each of the one or more joint blocks may further include a pair of first slits that is respectively formed in the pair of first side surfaces and open from the upper portion toward the connecting portion and a pair of second slits that is respectively formed in the pair of second side surfaces and open from the lower portion toward the connecting portion, the first extension is disposed in each of the first slits to connect the upper portion to the connecting portion, and the second extension may be disposed in each of the second slits to connect the lower portion to the connecting portion.

The pair of first slits may be in communication with the upper slit, the pair of second slits may be in communication with the lower slit, each of the first slits may include a pair of (1-1)-th slit portions positioned in respective sides of the first extension along a height direction of the first extension and a pair of (1-2)-th slit portions extending from respective lower ends of the pair of (1-1)-th slit portions toward respective ends of the first extension in a width direction of the first extension, and each of the second slits may include a pair of (2-1)-th slit portions positioned in respective sides of the second extension along a height direction of the second extension and a pair of (2-2)-th slit portions extending from respective upper ends of the pair of (2-1)-th slit portions toward respective ends of the second extension in a width direction of the second extension.

According to another aspect, there is provided a joint block configured to tiltably connect a first structure to a second structure, the joint block having a cuboid shape including an upper surface to which the first structure is connected, a lower surface to which the second structure is connected, a pair of first side surfaces configured to connect the upper surface to the lower surface in parallel, and a pair of second side surfaces vertically connected to the pair of first side surfaces, wherein the joint block may include an upper portion configured to form the upper surface, a lower portion configured to form the lower surface, a connecting portion configured to connect the upper portion to the lower portion and form the pair of first side surfaces and the pair of second side surfaces, an upper slit formed along at least a portion of a perimeter direction of the pair of first side surfaces and the pair of second side surfaces to space the upper portion apart from the connecting portion, a lower slit formed along at least a portion of the perimeter direction of the pair of first side surfaces and the pair of second side surfaces to space the lower portion apart from the connecting portion, and a hollow passing through between the upper surface and the lower surface.

The joint block may further include a first extension formed on each of the first side surfaces to connect the upper portion to the connecting portion and a second extension formed on each of the second side surfaces to connect the lower portion to the connecting portion.

The joint block may further include a pair of first slits that is respectively formed in the pair of first side surfaces and open from the upper portion toward the connecting portion and a pair of second slits that is respectively formed in the pair of second side surfaces and open from the lower portion toward the connecting portion, wherein the first extension may be disposed in each of the first slits to connect the upper portion to the connecting portion, and wherein the second extension may be disposed in each of the second slits to connect the lower portion to the connecting portion.

The pair of first slits may be in communication with the upper slit, the pair of second slits may be in communication with the lower slit, each of the first slits may include a pair of (1-1)-th slit portions positioned in respective sides of the first extension along a height direction of the first extension and a pair of (1-2)-th slit portions extending from respective lower ends of the pair of (1-1)-th slit portions toward respective ends of the first extension in a width direction of the first extension, and each of the second slits may include a pair of (2-1)-th slit portions positioned in respective sides of the second extension along a height direction of the second extension and a pair of (2-2)-th slit portions extending from respective upper ends of the pair of (2-1)-th slit portions toward respective ends of the second extension in a width direction of the second extension.

According to another aspect, there is provided a substrate-polishing system including a polishing surface plate configured to rotate about an axis perpendicular to a ground surface, wherein a polishing pad is disposed on an upper portion of the polishing surface plate, a substrate carrier including a carrier head configured to rotate about a rotation axis, wherein a lower portion of the substrate carrier is configured to grip a substrate, and a pressurizing structure connected to the substrate carrier and configured to partially be in contact with an upper portion of the carrier head to apply a biased load to the carrier head, wherein the pressurizing structure may include a plurality of load-generating devices with adjustable height disposed to form equal angles about the rotation axis of the carrier head, an upper ring bracket having a ring shape and connected to lower portions of the plurality of load-generating devices, and a lower ring bracket connected to an inner circumferential surface of the upper ring bracket via a bearing to be rotatable with respect to the upper ring bracket and configured to apply a load to the upper portion of the carrier head, and wherein each of the plurality of load-generating devices may include an actuator including a cylinder member and a piston member configured to slide relative to each other and a lower joint block configured to connect the actuator to the upper ring bracket such that the actuator and the upper ring bracket tilt relative to each other.

Additional aspects of embodiments will be set forth in part in the description which follows and, in part, will be apparent from the description, or may be learned by practice of the disclosure.

According to embodiments, a substrate-polishing device may eliminate imbalance in a substrate-polishing profile, particularly imbalance in a polishing profile at an edge region of the substrate.

According to embodiments, a substrate-polishing device may apply a biased load to a retainer ring for controlling a polishing profile at the edge of a substrate.

According to embodiments, a substrate-polishing device may reduce a rebound phenomenon that may occur during a substrate-polishing process.

The effects of the substrate-polishing device, according to an embodiment, are not limited to the foregoing effects, and unstated effects may be clearly understood by those skilled in the art from the description below.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a perspective view of a substrate-polishing system according to an embodiment;

FIG. 2 is a cross-sectional view of a substrate-polishing system according to an embodiment;

FIG. 3A is a perspective view of a pressurizing structure according to an embodiment;

FIG. 3B is a cross-sectional view of a pressurizing structure taken along A-A' of FIG. 3A, according to an embodiment;

FIG. 4 is a perspective view of a joint block according to an embodiment; and

FIGS. 5A and 5B are cross-sectional views of a substrate-polishing system illustrating an operation of a pressurizing structure, according to an embodiment.

### DETAILED DESCRIPTION

Hereinafter, embodiments are described in detail with reference to the accompanying drawings. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. As used herein, the singular forms "a," "an," and "the" are intended to include the plural forms as well, unless the context clearly indicates otherwise. It will be further understood that the terms "comprises/comprising" or "includes/including" when used herein, specify the presence of stated features, integers, steps, operations, elements, components, or groups thereof, but do not preclude the presence or addition of one or more other features, integers, steps, operations, elements, components, or groups thereof.

Unless otherwise defined, all terms including technical and scientific terms used herein have the same meaning as commonly understood by one of ordinary skill in the art to which embodiments belong. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

When describing the embodiments with reference to the accompanying drawings, like reference numerals refer to like components regardless of drawing numbers and a repeated description related thereto will be omitted. In the description of embodiments, detailed description of well-known related technology will be omitted when it is deemed that such description will cause ambiguous interpretation of the present disclosure.

Also, in the description of the components, terms such as first, second, A, B, (a), (b) or the like may be used herein when describing components of the disclosure. These terms are used only for the purpose of discriminating one component from another component, and the nature, the sequences, or the orders of the components are not limited by the terms. When one component is described as being "connected," "coupled," or "attached" to another component, it should be understood that one component may be connected or attached directly to another component, and an intervening component may also be "connected," "coupled," or "attached" to the components.

Components included in an embodiment and components that have common functions will be described using the same names in other embodiments. Unless stated otherwise, the description of any one embodiment may be applied to other examples, and the specific description of the repeated configuration will be omitted.

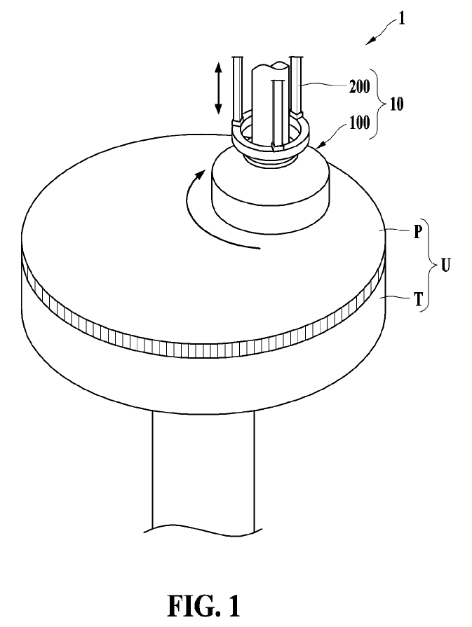

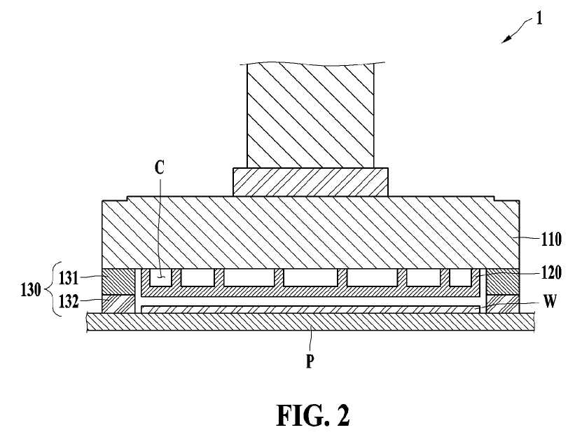

FIG. 1 is a perspective view of a substrate-polishing system according to an embodiment. FIG. 2 is a cross-sectional view of a substrate-polishing system according to an embodiment.

Referring to FIGS. 1 and 2, a substrate-polishing system 1 according to an embodiment may perform the process of polishing a substrate W. The process of polishing the substrate W may include not only the process of directly polishing the substrate W but also the process of conditioning a polishing pad P and the process of supplying slurry onto the substrate W. The substrate W may be a silicon wafer for manufacturing a semiconductor device. However, the type of the substrate W is not limited thereto. For example, the substrate W may include glass for a flat panel display device (FPD), such as a liquid crystal display (LCD) and a plasma display panel (PDP).

The substrate-polishing system 1 according to an embodiment may include a polishing unit U and a substrate-polishing device 10. In an embodiment, the polishing unit U may include a polishing surface plate T and the polishing pad P connected to the polishing surface plate T. For example, the polishing pad P may be disposed on the upper portion of the polishing surface plate T. The polishing surface plate T may rotate about a rotation axis perpendicular to the ground. As the polishing surface plate T rotates, the polishing pad P may rotate together therewith about the rotation axis. The polishing pad P may be in contact with the surface of the substrate W to be polished and physically wear the surface of the substrate W to be polished. For example, the polishing pad P may include a polyurethane material.

The substrate-polishing device 10 according to an embodiment may include a substrate carrier 100 and a pressurizing structure 200 connected to the substrate carrier 100.

In an embodiment, the substrate carrier 100 may grip the substrate W. The substrate carrier 100 may chuck and grip the substrate W to be polished and move the substrate W upward toward the polishing pad P. The substrate carrier 100 may polish the substrate W by bringing the substrate W, which is transferred to the upper portion of the polishing pad P, into contact with the polishing pad P. The substrate carrier 100 may control the degree of polishing of the substrate W by controlling the frictional force between the substrate W and the polishing pad P by applying pressure to the substrate W that is in contact with the polishing pad P.

In an embodiment, the substrate carrier 100 may control the position of the substrate W. The substrate carrier 100 may receive power from the outside and may rotate about an axis perpendicular to the surface of the polishing pad P. As the substrate carrier 100 rotates, the substrate W that is gripped may be polished while rotating in contact with the polishing pad P.

In an embodiment, the substrate carrier 100 may move the substrate W in an up-and-down direction relative to the ground. The substrate carrier 100 may move up and down relative to a substrate support (not shown) for chucking/de-chucking the substrate W or may move up and down relative to the polishing pad P for polishing the substrate W.

In an embodiment, the substrate carrier 100 may move the substrate W horizontally. For example, the substrate carrier 100 may perform translational motion on a plane parallel to the surface of the polishing pad P. The substrate carrier 100 may move the substrate W on the plane parallel to the surface of the polishing pad P. Consequently, depending on the horizontal and/or vertical movement of the substrate carrier 100, the substrate W may be transferred to a polishing position or removed from a polishing position.

The substrate carrier 100 according to an embodiment may include a carrier head 110, a membrane 120, and a retainer ring 130.

In an embodiment, the carrier head 110 may form at least a portion of the exterior of the substrate carrier 100. Various parts of the substrate carrier 100 may be connected to and/or disposed on the carrier head 110.

In an embodiment, the membrane 120 may be connected to the lower portion of the carrier head 110. The membrane 120 may adsorb and grip the substrate W. The membrane 120 may include an elastically deformable material. In an embodiment, the membrane 120 may grip the substrate W and, at the same time, apply pressure to the substrate W during the process of polishing the substrate W that is gripped. The pressure of each chamber C of the membrane 120 may be individually controlled. For example, a pressure-regulating portion (not shown) may be connected to each chamber C to regulate the pressure of each chamber C through a fluid (e.g., air), and the pressure of each chamber C may be individually regulated by the pressure-regulating portion. By controlling the internal pressure of each chamber C through this structure, the polishing profile of a corresponding portion of the substrate W may be controlled.

In an embodiment, the retainer ring 130 may be connected to the lower portion of the carrier head 110 to enclose, from the outside, the substrate W gripped by the membrane 120. The retainer ring 130 may support the edge of the substrate W gripped by the substrate carrier 100, thereby preventing the substrate W from detaching from the substrate carrier 100. For example, the retainer ring 130 may support a side surface of the substrate W so that the substrate W does not detach from the substrate carrier 100 due to vibration and/or friction occurring during the substrate-polishing process.

The retainer ring 130 according to an embodiment may include an upper retainer ring 131 and a lower retainer ring 132. The upper retainer ring 131 may be formed in a ring shape. For example, the upper retainer ring 131 may include a metal material to stably grip a substrate. The lower retainer ring 132 may be connected to the lower portion of the upper retainer ring 131. The lower retainer ring 132 may be formed in a ring shape. As the process of polishing a substrate is performed, the lower retainer ring 132 may experience wear. The lower retainer ring 132, which undergoes wear, may be replaced. For example, the lower retainer ring 132 may include an engineering plastic material.

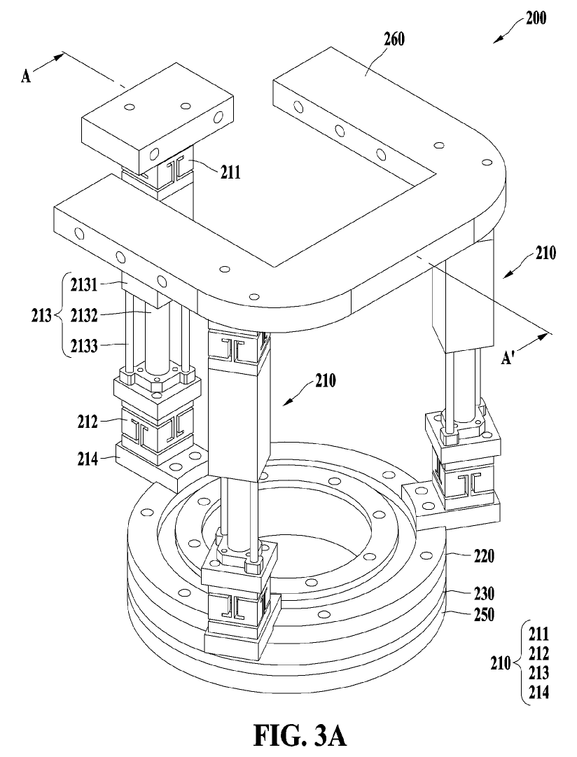

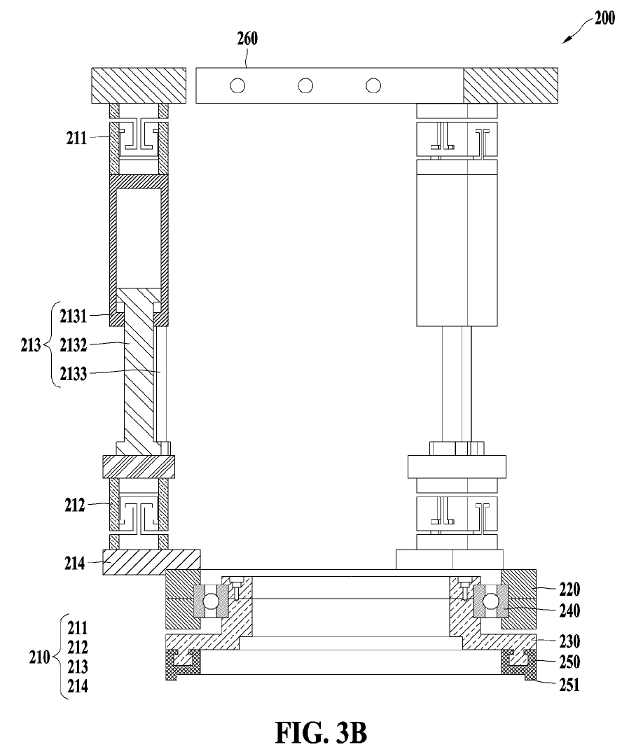

In an embodiment, the pressurizing structure 200 may be connected to the substrate carrier 100 and configured to apply a biased load to the carrier head 110. The pressurizing structure 200 may include a plurality of load-generating devices (e.g., 210 of FIG. 3A) with adjustable height. As the length of each of the plurality of load-generating devices 210 is adjusted, the lower side of the pressurizing structure (e.g., a rubber member 250 of the pressurizing structure 200 of FIG. 3A) may be in contact with the upper side of the carrier head 110. While the pressurizing structure 200 is in contact with the carrier head 110, the length of each of the plurality of load-generating devices 210 may be adjusted so that a biased load may be applied to the carrier head 110. For example, while the rubber member 250 is in contact with the carrier head 110, the length of one of the plurality of load-generating devices 210 may be adjusted so that the length of one of the plurality of load-generating devices 210 increases, thereby allowing a greater pressure to be applied to a portion of the rubber member 250 connected to the corresponding one of the plurality of load-generating devices 210. In addition, as the length of each of the plurality of load-generating devices 210 is differently adjusted, the rubber member 250 may tilt, and accordingly, a biased load may be applied to the carrier head 110. Hereinafter, the shape and operation of the pressurizing structure 200 according to an embodiment are described.

FIG. 3A is a perspective view of a pressurizing structure according to an embodiment. FIG. 3B is a cross-sectional view of a pressurizing structure taken along A-A' of FIG. 3A, according to an embodiment.

Referring to FIGS. 3A and 3B, the pressurizing structure 200 according to an embodiment may include a fixed plate 260, the plurality of load-generating devices 210, an upper ring bracket 220, a lower ring bracket 230, a bearing member 240, and the rubber member 250.

In an embodiment, the fixed plate 260 may be installed on the upper portion of a carrier head (e.g., 110 of FIG. 2). The height of the fixed plate 260 relative to the carrier head 110 may be maintained constant. For example, the fixed plate 260 may be positioned on a plane parallel to the rotation axis of the carrier head 110. For example, while the carrier head 110 rotates or the length of each of the plurality of load-generating devices 210 is adjusted, the gap between the carrier head 110 and the fixed plate 260 may be maintained constant.

In an embodiment, the plurality of load-generating devices 210 may be connected to the lower portion of the fixed plate 260. The plurality of load-generating devices 210 may be disposed to form equal angles around the rotation axis of the carrier head (e.g., 110 of FIG. 2). The plurality of load-generating devices 210 may be disposed so that the rotation axis of the carrier head 110 is positioned between the plurality of load-generating devices 210. As described below, each of the plurality of load-generating devices 210 may include an actuator 213. The height of the actuator 213 may be adjusted to press different portions of the carrier head 110. Although FIGS. 3A and 3B illustrate that the pressurizing structure 200 includes three load-generating devices (i.e., 210), the number of load-generating devices (i.e., 210) is not limited thereto, and two or more load-generating devices may be provided.

In an embodiment, the upper ring bracket 220 and the lower ring bracket 230 may be connected to the lower portion of the plurality of load-generating devices 210. The upper ring bracket 220 may be formed in a ring shape. The lower ring bracket 230 may be formed in a ring shape. The central axes of the upper ring bracket 220 and the lower ring bracket 230 may coincide with each other and substantially coincide with the rotation axis of the carrier head 110. In other words, the rotation axis of the carrier head 110 may be positioned inside the ring shapes of the upper ring bracket 220 and the lower ring bracket 230. The upper ring bracket 220 may be connected to the lower portions of the plurality of load-generating devices 210 such that the plurality of load-generating devices 210 is disposed at equal intervals along the circumferential direction of the upper ring bracket 220. For example, the upper ring bracket 220 may be fixedly connected to a connecting member 214 positioned on the lower side of the plurality of load-generating devices 210. The lower ring bracket 230 may be connected to the lower portion of the upper ring bracket 220 so that the central axes of the upper ring bracket 220 and the lower ring bracket 230 coincide with each other. For example, the lower ring bracket 230 may be connected to the upper ring bracket 220 such that the inner circumferential surface of the upper ring bracket 220 and the outer circumferential surface of the lower ring bracket 230 face each other.

In an embodiment, the lower ring bracket 230 may be rotatably connected to the upper ring bracket 220 by the bearing member 240. The bearing member 240 may connect the upper ring bracket 220 to the lower ring bracket 230 via a bearing. For example, the bearing member 240 may be disposed between the inner circumferential surface of the upper ring bracket 220 and the outer circumferential surface of the lower ring bracket 230. For example, the bearing member 240 may be a thrust bearing.

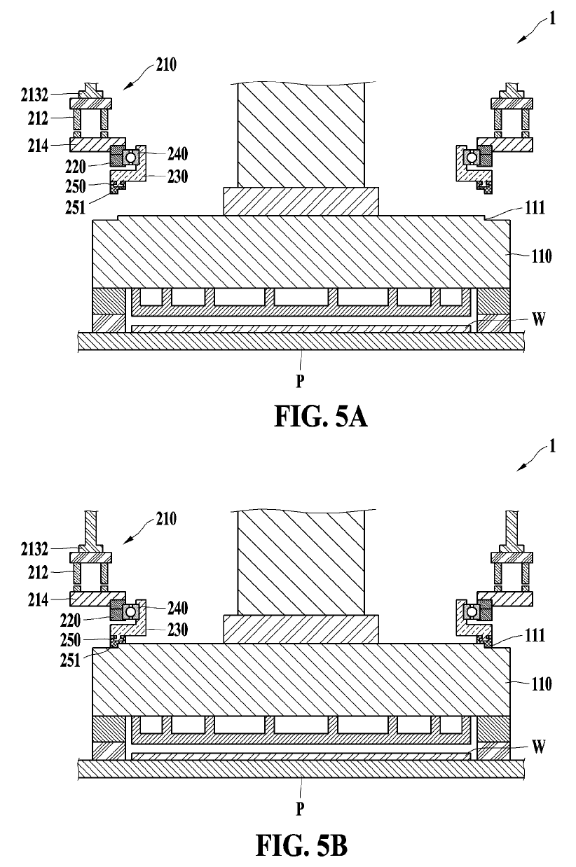

In an embodiment, the rubber member 250 may be connected to the lower portion of the lower ring bracket 230. The rubber member 250, similar to the upper ring bracket 220 and the lower ring bracket 230, may be formed in a ring shape. The rubber member 250 may be in direct contact with the carrier head (e.g., 110 of FIG. 5A) as the length of each of the plurality of load-generating devices 210 is adjusted. In this case, the diameter of the rubber member 250 may be less than the diameter of the carrier head 110. The rubber member 250 may include a first coupling portion 251 formed on the lower side of the rubber member 250 and configured to be in contact with the carrier head (e.g., 110 of FIG. 5A). The carrier head 110 may include a second coupling portion (e.g., 111 of FIG. 5A) formed on the upper side of the carrier head 110 and configured to be in contact with the rubber member 250. The second coupling portion 111 may be formed in a shape that engages with the first coupling portion 251. For example, the first coupling portion 251 may be formed in a ring shape that protrudes downward from the lower side surface of the rubber member 250. For example, the second coupling portion 111 may be formed in a ring shape that is recessed from the upper side surface of the carrier head 110. According to this structure, when the rubber member 250 is in contact with the upper surface of the carrier head 110 by the operation of the pressurizing structure 200, the first coupling portion 251 of the rubber member 250 may be engaged with and connected to the second coupling portion 111 of the carrier head 110, thereby stably maintaining the contact state between the carrier head 110 and the rubber member 250. The lower ring bracket 230 and the rubber member 250 may rotate together with the carrier head 110 while in contact with the carrier head 110. While the carrier head 110 rotates, a biased load may be applied to the carrier head 110 from the upper side to the lower side by the rubber member 250.

In an embodiment, each of the plurality of load-generating devices 210 may include the actuator 213 and an upper joint block 211 and a lower joint block 212 that are connected to respective sides of the actuator 213.

In an embodiment, the actuator 213 may include a cylinder member 2131 and a piston member 2132. The cylinder member 2131 and the piston member 2132 may slide relative to each other to enable height adjustment. By relative movement between the cylinder member 2131 and the piston member 2132, the length of a load-generating device (i.e., 210) may be adjusted, and the rubber member 250 connected to the lower portion of the load-generating device (i.e., 210) may press the carrier head 110. The actuator 213 may further include a guide piston member 2133 that is slidably connected to the cylinder member 2131. The guide piston member 2133 may be configured to guide sliding between the cylinder member 2131 and the piston member 2132. However, the components of the actuator 213 are not limited to the cylinder member 2131 and the piston member 2132. For example, the actuator 213 may include a link structure or a linear actuator that enables height adjustment of each of the plurality of load-generating devices 210.

In an embodiment, the upper joint block 211 and the lower joint block 212 may each connect the actuator 213 to different components of the pressurizing structure 200. For example, the upper joint block 211 may connect the actuator (e.g., the cylinder member 2131) to the fixed plate 260. For example, the lower joint block 212 may connect the actuator (e.g., the piston member 2132) to the upper ring bracket 220.

In an embodiment, the upper joint block 211 and the lower joint block 212 may each be deformed to maintain the connection between the plurality of load-generating devices 210 and the upper ring bracket 220. Even when the plurality of load-generating devices 210 is adjusted to have different heights, the connection between the plurality of load-generating devices 210 and the upper ring bracket 220 may be maintained. In other words, each of the upper joint block 211 and the lower joint block 212 may implement a relative tilting motion between connected structures. For example, the upper joint block 211 may implement a relative tilting motion between the fixed plate 260 and the actuator (e.g., the cylinder member 2131). For example, the lower joint block 212 may implement a relative tilting motion between the actuator (e.g., the piston member 2132) and the upper ring bracket 220. With this structure, the upper ring bracket 220, the lower ring bracket 230, and the rubber member 250 may tilt with respect to the rotation axis of the carrier head (e.g., 110 of FIG. 2). When the upper ring bracket 220, the lower ring bracket 230, and the rubber member 250 are in a tilted state, the rubber member 250 may be in contact with the carrier head 110.

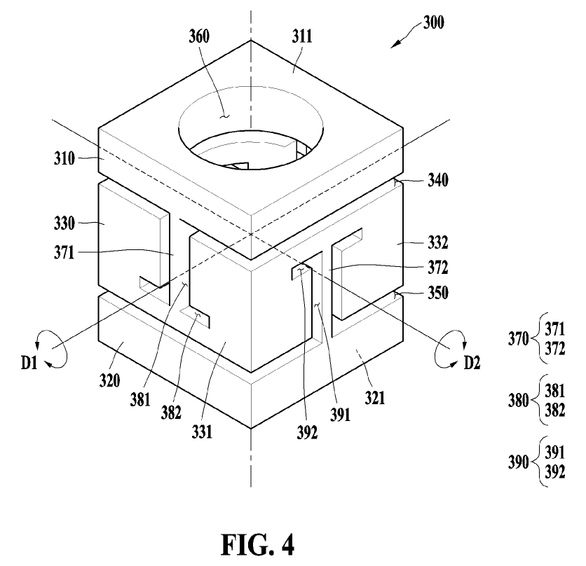

FIG. 4 is a perspective view of a joint block according to an embodiment.

An upper joint block (e.g., 211 of FIG. 3A) may have the same structure as a lower joint block (e.g., 212 of FIG. 3A). Hereinafter, a joint block 300 that connects a first structure to a second structure is described as an example. The description of the joint block 300 may also apply to the upper joint block 211 and the lower joint block 212.

Referring to FIG. 4, the joint block 300 according to an embodiment may be formed in a cuboid shape including an upper surface 311, a lower surface 321, a pair of first side surfaces 331, and a pair of second side surfaces 332. In an embodiment, the upper surface 311 and the lower surface 321 may each have a square shape. In this case, the pair of first side surfaces 331 may have the same width as the pair of second side surfaces 332. The upper surface 311 and the lower surface 321 may be portions to which different structures are connected. For example, a fixed plate (e.g., 260 of FIG. 3A) may be connected to the upper surface 311 of the upper joint block (e.g., 211 of FIG. 3A), and a cylinder member (e.g., 2131 of FIG. 3A) may be connected to the lower surface 321 of the upper joint block 211. The pair of first side surfaces 331 parallel to each other may connect the upper surface 311 to the lower surface 321 in parallel. The pair of second side surfaces 332 parallel to each other may connect the upper surface 311 to the lower surface 321 in parallel. The pair of first side surfaces 331 may be vertically connected to the pair of second side surfaces 332. A hollow 360 passing through between the upper surface 311 and the lower surface 321 may be formed inside the cuboid. The hollow 360 may be formed in a cylindrical shape along the height direction of the cuboid. The central axis of the hollow 360 that has the cylindrical shape may coincide with the central axis in the height direction of the cuboid. The height direction of the hollow 360 may be parallel to the direction in which the cylinder member (e.g., 2131 of FIG. 3B) and the piston member (e.g., 2132 of FIG. 3B) slide relative to each other. In FIG. 4, the hollow 360 is illustrated as being formed in a cylindrical shape along the height direction of the hollow 360, and the hollow 360 may also be formed in a cuboid shape along the height direction of the hollow 360.

The joint block 300 according to an embodiment may include an upper portion 310, a lower portion 320, a connecting portion 330 connecting the upper portion 310 to the lower portion 320, an upper slit 340 formed between the upper portion 310 and the connecting portion 330, and a lower slit 350 formed between the connecting portion 330 and the lower portion 320. The upper portion 310 may form the upper surface 311. The lower portion 320 may form the lower surface 321. The connecting portion 330 may form the pair of first side surfaces 331 and the pair of second side surfaces 332. The upper portion 310 and the connecting portion 330 may be separated from each other by the upper slit 340. The upper slit 340 may be formed in at least a portion of the perimeter direction of the pair of first side surfaces 331 and the pair of second side surfaces 332. The connecting portion 330 and the lower portion 320 may be separated from each other by the lower slit 350. The lower slit 350 may be formed in at least a portion of the perimeter direction of the pair of first side surfaces 331 and the pair of second side surfaces 332. In other words, the joint block 300 may include the upper portion 310, the upper slit 340, the connecting portion 330, the lower slit 350, and the lower portion 320 along the height direction of the joint block 300.

In an embodiment, the joint block 300 may further include an extension 370 for connecting the upper portion 310, the lower portion 320, and/or the connecting portion 330 to one another. The extension 370 may include a pair of first extensions 371 formed to connect the upper portion 310 to the connecting portion 330 and a pair of second extensions 372 formed to connect the connecting portion 330 to the lower portion 320. The pair of first extensions 371 may each be formed on a corresponding one of the pair of first side surfaces 331 to connect the upper portion 310 to the connecting portion 330. For example, the pair of first extensions 371 may each be disposed at the widthwise center of a corresponding one of the pair of first side surfaces 331. The pair of second extensions 372 may each be formed on a corresponding one of the pair of second side surfaces 332 to connect the connecting portion 330 to the lower portion 320. For example, the pair of second extensions 372 may each be disposed at the widthwise center of a corresponding one of the pair of second side surfaces 332.

In an embodiment, the joint block 300 may further include a pair of first slits 380 formed in the pair of first side surfaces 331 and a pair of second slits 390 formed in the pair of second side surfaces 332. The pair of first slits 380 may be open in the direction from the upper portion 310 toward the connecting portion 330 and may be in communication with the upper slit 340. The pair of first extensions 371 may each be disposed in a corresponding one of the pair of first slits 380. The pair of second slits 390 may be open in the direction from the lower portion 320 toward the connecting portion 330 and may be in communication with the lower slit 350. The pair of second extensions 372 may each be disposed in a corresponding one of the pair of second slits 390.

In an embodiment, each of the first slits 380 may include a pair of (1-1)-th slit portions 381 extending in the height direction of the pair of first side surfaces 331 and include a pair of (1-2)-th slit portions 382 extending in the width direction of the pair of first side surfaces 331. The pair of (1-1)-th slit portions 381 may be positioned in respective sides of the pair of first extensions 371 in the height direction of the pair of first extensions 371 so that the pair of first extensions 371 is disposed in the pair of first slits 380. The pair of (1-2)-th slit portions 382 may extend from respective ends (e.g., lower ends) of the pair of (1-1)-th slit portions 381 toward respective ends of the pair of first extensions 371 in the width direction of the pair of first extensions 371. The pair of (1-1)-th slit portions 381, the pair of (1-2)-th slit portions 382, and the upper slit 340 may be formed to have substantially the same width. The pair of (1-1)-th slit portions 381 and the pair of (1-2)-th slit portions 382 may be formed symmetrically with respect to the pair of first extensions 371.

In an embodiment, each of the second slits 390 may include a pair of (2-1)-th slit portions 391 extending in the height direction of the pair of second side surfaces 332 and a pair of (2-2)-th slit portions 392 extending in the width direction of the pair of second side surfaces 332. The pair of (2-1)-th slit portions 391 may be positioned in respective sides of the pair of second extensions 372 in the height direction of the pair of second extensions 372 so that the pair of second extensions 372 is disposed in the pair of second slits 390. The pair of (2-2)-th slit portions 392 may extend from respective ends (e.g., upper ends) of the pair of (2-1)-th slit portions 391 toward respective ends of the pair of second extensions 372 in the width direction of the pair of second extensions 372. The pair of (2-1)-th slit portions 391, the pair of (2-2)-th slit portions 392, and the lower slit 350 may be formed to have substantially the same width. The pair of (2-1)-th slit portions 391 and the pair of (2-2)-th slit portions 392 may be formed symmetrically with respect to the pair of second extensions 372.

In an embodiment, the joint block 300 may include a metal material. For example, the joint block 300 may include aluminum. The upper portion 310, the lower portion 320, the connecting portion 330, the first extension 371, and the second extension 372 of the joint block 300 may be integrally formed as one body. While the joint block 300 is in use, relative tilting may occur between a structure connected to the upper surface 311 of the joint block 300 and a structure connected to the lower surface 321 of the joint block 300. For example, tilting between structures may occur based on a first axis D1 and/or a second axis D2 perpendicular to the height direction of the joint block 300. In this case, bending of the pair of first extensions 371 may occur within the pair of first slits 380 and bending of the pair of second extensions 372 may occur within the pair of second slits 390. Therefore, even when relative tilting occurs between connected structures, the joint block 300 may maintain the connection between the structures. In other words, the joint block 300 may implement a relative tilting motion between the connected structures.

In an embodiment, the joint block 300 may be configured to tilt a first structure and a second structure relative to each other around the first axis D1 perpendicular to the height direction through a change in the gap between the upper portion 310 and the connecting portion 330 and a partial change in the positions of the pair first extensions 371 in the pair of first slits 380. In an embodiment, the joint block 300 may be configured to tilt the first structure and the second structure relative to each other around the second axis D2 perpendicular to the height direction and the first axis D1 through a change in the gap between the lower portion 320 and the connecting portion 330 and a partial change in the positions of the pair of second extensions 372 in the pair of second slits 390. Accordingly, through partial deformation of the joint block 300, the angle formed by the lower surface 312 relative to the upper surface 311 may be changed. In other words, the upper surface 311 and the lower surface 312 may tilt relative to each other. Accordingly, the angle formed by the first structure connected to the upper surface 311 and the second structure connected to the lower surface 312 changes, and the first structure and the second structure may tilt relative to each other. For example, the upper joint block 211 may implement a partial tilting motion between the fixed plate 260 and the actuator 213. For example, the lower joint block 212 may implement a partial tilting motion between the actuator 213 and the upper ring bracket 220.

In an embodiment, as the widths of the pair of first side surfaces 331 are the same as the widths of the pair of second side surfaces 332, the tiltable range centered on the first axis D1 may be substantially the same as the tiltable range centered on the second axis D2. The tiltable range of the joint block 300 may be limited by the material and/or shape of the joint block 300. For example, when relative tilting occurs between the upper surface 311 and the lower surface 321 around the first axis D1, the upper slit 340 may be deformed and the upper portion 310 and the connecting portion 330 may be in contact with each other, thereby limiting the tiltable range. For example, when relative tilting occurs between the upper surface 311 and the lower surface 321 around the second axis D2, the lower slit 350 may be deformed and the lower portion 320 and the connecting portion 330 may be in contact with each other, thereby limiting the tiltable range. In this case, the limit at which partial deformation of the upper slit 340 and the pair of first extensions 371 occurs during tilting around the first axis D1 may be substantially the same as the limit at which partial deformation of the lower slit 350 and the pair of second extensions 372 occurs during tilting around the second axis D2.

FIGS. 5A and 5B are cross-sectional views of a substrate-polishing system illustrating an operation of a pressurizing structure, according to an embodiment.

The pressurizing structure 200 illustrated in FIGS. 5A and 5B is an example. For ease of description, FIGS. 5A and 5B illustrate the pressurizing structure 200 including four load-generating devices (i.e., 210).

In an embodiment, the pressurizing structure 200 may be disposed on the upper portion of the carrier head 110. As the length of each of the plurality of load-generating devices 210 is adjusted, the position of the rubber member 250 with respect to the carrier head 110 may be adjusted. The rubber member 250 may be spaced apart from the upper side of the carrier head 110 (refer to FIG. 5A) or may be in contact with the upper side of the carrier head 110 (refer to FIG. 5B). When the rubber member 250 is in contact with the carrier head 110, the first coupling portion 251 of the rubber member 250 may engage with the second coupling portion 111 of the carrier head 110. While the rubber member 250 is in contact with the carrier head 110, the carrier head 110 may rotate about a rotation axis. As the carrier head 110 rotates, the rubber member 250 in contact with the upper side of the carrier head 110 may rotate together with the carrier head 110. The rubber member 250 and the lower ring bracket 230 may rotate relative to the upper ring bracket 220.

In an embodiment, while the carrier head 110 rotates, the pressurizing structure 200 may apply a biased load to the upper side of the carrier head 110. For example, as the length of each of the plurality of load-generating devices 210 is adjusted, the degree to which the rubber member 250 presses the carrier head 110 may be adjusted. As the length of each of the plurality of load-generating devices 210 is adjusted, the rubber member 250 may tilt. The rubber member 250 in a tilted state may press the carrier head 110, and the pressure applied to the edge of the substrate W may be increased and/or decreased. With this structure, the polishing profile of a substrate may be improved, and the rebound phenomenon that may occur during the process of polishing the substrate may be reduced.

As described above, although the embodiments have been described with reference to the limited drawings, one of ordinary skill in the art may apply various technical modifications and variations based thereon. For example, suitable results may be achieved if the described techniques are performed in a different order, and/or if components in a described system, architecture, device, or circuit are combined in a different manner, and/or replaced or supplemented by other components or their equivalents.

Therefore, other implementations, other embodiments, and equivalents to the claims are also within the scope of the following claims.

What is claimed is:

1. A substrate-polishing device comprising:
a substrate carrier comprising a carrier head configured to rotate about a rotation axis, wherein a lower portion of the substrate carrier is configured to grip a substrate; and
a pressurizing structure connected to the substrate carrier and configured to partially be in contact with an upper portion of the carrier head to apply a biased load to the carrier head,
wherein the pressurizing structure comprises a plurality of load-generating devices with adjustable height and is configured to apply a biased load to the carrier head through the plurality of load-generating devices.

2. The substrate-polishing device of claim 1, wherein the plurality of load-generating devices is disposed to form equal angles about the rotation axis of the carrier head.

3. The substrate-polishing device of claim 2, wherein the pressurizing structure further comprises:
a fixed plate installed on the upper portion of the carrier head, wherein the plurality of load-generating devices is connected to a lower portion of the fixed plate;
an upper ring bracket having a ring shape and connected to lower portions of the plurality of load-generating devices;
a lower ring bracket having a ring shape and rotatably connected to the upper ring bracket to have a same central axis as the upper ring bracket; and
a bearing member configured to connect the upper ring bracket to the lower ring bracket via a bearing.

4. The substrate-polishing device of claim 3, wherein
the upper ring bracket is connected to the lower ring bracket such that an inner circumferential surface of the upper ring bracket and an outer circumferential surface of the lower ring bracket face each other, and
the bearing member is disposed between the inner circumferential surface of the upper ring bracket and the outer circumferential surface of the lower ring bracket.

5. The substrate-polishing device of claim 3, wherein
the pressurizing structure comprises a rubber member having a ring shape, connected to a lower portion of the lower ring bracket, and comprising a cushioning material,
the rubber member comprises a first coupling portion formed on a lower side of the rubber member and configured to be in contact with the carrier head, and
the carrier head comprises a second coupling portion formed on an upper side of the carrier head and configured to engage with the first coupling portion.

6. The substrate-polishing device of claim 5, wherein each of the plurality of load-generating devices comprises:
an actuator comprising a cylinder member and a piston member configured to slide relative to each other in a height direction; and
one or more joint blocks configured to connect the fixed plate to the upper ring bracket and implement a relative tilting motion of the upper ring bracket with respect to the fixed plate.

7. The substrate-polishing device of claim 6, wherein the one or more joint blocks comprise an upper joint block configured to connect the fixed plate to the cylinder member and implement a relative tilting motion between the fixed plate and the cylinder member.

8. The substrate-polishing device of claim 6, wherein the one or more joint blocks comprise a lower joint block configured to connect the piston member to the upper ring bracket and implement a relative tilting motion between the piston member and the upper ring bracket.

9. The substrate-polishing device of claim 8, wherein each of the one or more joint blocks has a cuboid shape comprising an upper surface and a lower surface to which different structures are connected, a pair of first side surfaces configured to connect the upper surface to the lower surface in parallel, and a pair of second side surfaces vertically connected to the pair of first side surfaces.

10. The substrate-polishing device of claim 9, wherein each of the one or more joint blocks comprises:
an upper portion configured to form the upper surface;
a lower portion configured to form the lower surface;
a connecting portion configured to connect the upper portion to the lower portion and form the pair of first side surfaces and the pair of second side surfaces;
an upper slit formed along at least a portion of a perimeter direction of the pair of first side surfaces and the pair of second side surfaces to space the upper portion apart from the connecting portion; and
a lower slit formed along at least a portion of the perimeter direction of the pair of first side surfaces and the pair of second side surfaces to space the lower portion apart from the connecting portion.

11. The substrate-polishing device of claim 10, wherein
each of the one or more joint blocks further comprises a hollow passing through between the upper surface and the lower surface, and
a height direction of the hollow is parallel to a height direction of each of the plurality of load-generating devices.

12. The substrate-polishing device of claim 11, wherein each of the one or more joint blocks further comprises:
a first extension formed on each of the first side surfaces to connect the upper portion to the connecting portion; and
a second extension formed on each of the second side surfaces to connect the lower portion to the connecting portion.

13. The substrate-polishing device of claim 12, wherein
the first extension is disposed at a widthwise center of each of the first side surfaces, and
the second extension is disposed at a widthwise center of each of the second side surfaces.

14. The substrate-polishing device of claim 12, wherein
each of the one or more joint blocks further comprises:
a pair of first slits that is respectively formed in the pair of first side surfaces and open from the upper portion toward the connecting portion; and
a pair of second slits that is respectively formed in the pair of second side surfaces and open from the lower portion toward the connecting portion,
the first extension is disposed in each of the first slits to connect the upper portion to the connecting portion, and
the second extension is disposed in each of the second slits to connect the lower portion to the connecting portion.

15. The substrate-polishing device of claim 14, wherein
the pair of first slits is in communication with the upper slit,
the pair of second slits is in communication with the lower slit,
each of the first slits comprises:
a pair of (1-1)-th slit portions positioned in respective sides of the first extension along a height direction of the first extension; and
a pair of (1-2)-th slit portions extending from respective lower ends of the pair of (1-1)-th slit portions toward respective ends of the first extension in a width direction of the first extension, and
each of the second slits comprises:
a pair of (2-1)-th slit portions positioned in respective sides of the second extension along a height direction of the second extension; and
a pair of (2-2)-th slit portions extending from respective upper ends of the pair of (2-1)-th slit portions toward respective ends of the second extension in a width direction of the second extension.

16. A joint block configured to tiltably connect a first structure to a second structure,
the joint block having a cuboid shape comprising an upper surface to which the first structure is connected, a lower surface to which the second structure is connected, a pair of first side surfaces configured to connect the upper surface to the lower surface in parallel, and a pair of second side surfaces vertically connected to the pair of first side surfaces,
wherein the joint block comprises:
an upper portion configured to form the upper surface;
a lower portion configured to form the lower surface;
a connecting portion configured to connect the upper portion to the lower portion and form the pair of first side surfaces and the pair of second side surfaces;
an upper slit formed along at least a portion of a perimeter direction of the pair of first side surfaces and the pair of second side surfaces to space the upper portion apart from the connecting portion;
a lower slit formed along at least a portion of the perimeter direction of the pair of first side surfaces and the pair of second side surfaces to space the lower portion apart from the connecting portion; and
a hollow passing through between the upper surface and the lower surface.

17. The joint block of claim 16, further comprising:
a first extension formed on each of the first side surfaces to connect the upper portion to the connecting portion; and
a second extension formed on each of the second side surfaces to connect the lower portion to the connecting portion.

18. The joint block of claim 17, further comprising:
a pair of first slits that is respectively formed in the pair of first side surfaces and open from the upper portion toward the connecting portion; and
a pair of second slits that is respectively formed in the pair of second side surfaces and open from the lower portion toward the connecting portion,
wherein the first extension is disposed in each of the first slits to connect the upper portion to the connecting portion, and
wherein the second extension is disposed in each of the second slits to connect the lower portion to the connecting portion.

19. The joint block of claim 18, wherein
the pair of first slits is in communication with the upper slit,
the pair of second slits is in communication with the lower slit,
each of the first slits comprises:
a pair of (1-1)-th slit portions positioned in respective sides of the first extension along a height direction of the first extension; and
a pair of (1-2)-th slit portions extending from respective lower ends of the pair of (1-1)-th slit portions toward respective ends of the first extension in a width direction of the first extension, and
each of the second slits comprises:
a pair of (2-1)-th slit portions positioned in respective sides of the second extension along a height direction of the second extension; and
a pair of (2-2)-th slit portions extending from respective upper ends of the pair of (2-1)-th slit portions toward respective ends of the second extension in a width direction of the second extension.

20. A substrate-polishing system comprising:
a polishing surface plate configured to rotate about an axis perpendicular to a ground surface, wherein a polishing pad is disposed on an upper portion of the polishing surface plate;
a substrate carrier comprising a carrier head configured to rotate about a rotation axis, wherein a lower portion of the substrate carrier is configured to grip a substrate; and
a pressurizing structure connected to the substrate carrier and configured to partially be in contact with an upper portion of the carrier head to apply a biased load to the carrier head,
wherein the pressurizing structure comprises:
a plurality of load-generating devices with adjustable height disposed to form equal angles about the rotation axis of the carrier head;
an upper ring bracket having a ring shape and connected to lower portions of the plurality of load-generating devices; and
a lower ring bracket connected to an inner circumferential surface of the upper ring bracket via a bearing to be rotatable with respect to the upper ring bracket and configured to apply a load to the upper portion of the carrier head, and
wherein each of the plurality of load-generating devices comprises:
an actuator comprising a cylinder member and a piston member configured to slide relative to each other; and
a lower joint block configured to connect the actuator to the upper ring bracket such that the actuator and the upper ring bracket tilt relative to each other.
